(19) United States
(12) Patent Application Publication
(10) Pub. No.: US 2015/0162517 A1
(43) Pub. Date: Jun. 11, 2015

(54) VOLTAGE GENERATION ACROSS TEMPERATURE DIFFERENTIALS THROUGH A FLEXIBLE THIN FILM THERMOELECTRIC DEVICE

(71) Applicant: Sridhar Kasichainula, Fremont, CA (US)

(72) Inventor: Sridhar Kasichainula, Fremont, CA (US)

(21) Appl. No.: 14/564,072

(22) Filed: Dec. 8, 2014

Related U.S. Application Data
(60) Provisional application No. 61/912,561, filed on Dec. 6, 2013.

(51) Int. Cl. H01L 35/32; H01L 31/052; H01L 35/34; H01L 35/30

(52) U.S. Cl. CPC H01L 35/32; H01L 35/30; H01L 31/0525; H01L 35/34

(57) ABSTRACT

A method and/or device of voltage generation across temperature differentials through a flexible thin film thermoelectric device is disclosed. A thin film thermoelectric layer is deposited onto a cell substrate. A thin film conduction layer is deposited above the thin film thermoelectric layer. The layered composite material is diced into thermoelectric cells. The thermoelectric cells are bonded to the electrically conductive pads of a top and bottom substrate, and are electrically connected in series. The resulting thin film thermoelectric device generates a voltage when exposed to a temperature gradient.

### CLAIM OF PRIORITY

This application is a conversion application of the U.S. Provisional Application No. 61/912,561 titled VOLTAGE GENERATION ACROSS TEMPERATURE DIFFERENTIALS THROUGH A THERMOELECTRIC LAYER COMPOSITE filed on Dec. 6, 2013.

### FIELD OF TECHNOLOGY

This disclosure relates generally to energy production, more particularly, to voltage generation across temperature differentials through a flexible thin film thermoelectric device

### BACKGROUND

A thermoelectric device is able to directly convert heat (i.e. a temperature gradient) into electricity. If their efficiency may be increased and the operational temperatures reduced to near room temperature (300K), thermoelectric devices may begin to supplant mechanical compressor refrigeration systems, gasoline generators, geothermal power production, and more. Thermoelectric devices may play a significant role in the energy production, home heating/cooling and general energy management of the future.

High thermal conductivity with lower electrical conductivity may prevent higher efficiency. Unfortunately, there are no single materials that possess simultaneously higher electrical conductivity and lower thermal conductivity. Low efficiency and high operating temperatures, combined with higher cost, prohibit current thermoelectric devices from wider market adoption. Low efficiency may relegate thermoelectric devices to a few applications where their simplicity and ruggedness may outweigh the inefficiency, such as sensors and waste-heat-energy converters. Furthermore, rigid thermoelectric devices are limited in their applications, especially when attempting to harvest energy from curved (e.g. pipes, etc.) or dynamic (e.g. the human body, etc.) sources.

### SUMMARY

Disclosed are a method, and apparatus of generation of a voltage from temperature differentials through a thin film thermoelectric device. It will be appreciated that the various embodiments discussed herein need not necessarily belong to the same group of exemplary embodiments, and may be grouped into various other embodiments not explicitly disclosed herein. In the following description, for purposes of explanation, numerous specific details are set forth in order to provide a thorough understanding of the various embodiments. Accordingly, the specification and drawings are to be regarded in an illustrative rather than a restrictive sense.

In one aspect, a thin film thermoelectric device includes at least one thermoelectric cell. Each thermoelectric cell includes a cell substrate, at least one thin film thermoelectric layer above the cell substrate, and at least one thin film conduction layer above the at least one thin film thermoelectric layer. Each of the thin film thermoelectric layers are separated by one of the at least one thin film conduction layers.

The thin film thermoelectric device may further include a plurality of thermoelectric cells, including N-type cells and P-type cells. The thin film thermoelectric device may also include a top substrate, a bottom substrate, and a plurality of electrically conductive pads disposed upon the top substrate and bottom substrate. The top layer of a thermoelectric cell may be the layer of the thermoelectric cell which is furthest away from the cell substrate.

The cell substrate and the top layer of each thermoelectric cell may be connected to the plurality of electrically conductive pads. The thermoelectric cells may be connected to each other in series through electrically conductive leads bridging pairs of electrically conductive pads, such that a first cell substrate is connected to a second cell substrate, and a first top layer is connected to a second top layer. Furthermore, the top substrate and the bottom substrate may be flexible.

The thermoelectric cell may include a barrier layer between a thin film thermoelectric layer and a thin film conduction layer. The barrier layer may be electrically conductive and may have a higher melting temperature than either of the thin film thermoelectric layer the thin film conduction layer being separated by the barrier layer.

The thermoelectric cell may further include a seed layer between the cell substrate and one of the at least one thin film thermoelectric layers. The seed layer may be electrically conductive, and may be an epoxy, a polymer film, a metallic compound applied as a thin film, and/or a material with a crystal structure which is intermediate to that of the cell substrate and the thin film thermoelectric layer.

The thermoelectric cell may further include a conductive adhesive layer between at least one thin film thermoelectric layer and at least one thin film conduction layer. The conductive adhesive layer may be electrically conductive, and may be an epoxy, a polymer film, a metallic compound applied as a thin film, and/or a material with a crystal structure which is intermediate to that of the thin film conduction layer and the thin film thermoelectric layer.

Furthermore, the at least one thin film thermoelectric layer and the at least one thin film conduction layer may be deposited using a sputtering process. Additionally, the at least one thin film thermoelectric layer may be no thicker than 5 microns, and the at least one thin film conduction layer may be between 1 microns and 15 microns. The thin film thermoelectric device may be configured for use in a wearable device, a solar panel, a curved surface, and/or a battery. Finally, the cell substrate may be a metallic foil.

In another aspect, a method of producing a thin film thermoelectric device includes producing at least two layered composite materials. The layered composite materials are produced by depositing at least one thin film thermoelectric layer onto a cell substrate, and depositing at least one thin film conduction layer, such that each of the at least one thin film thermoelectric layer are separated by one of the at least one thin film conduction layer. Next, the at least two layered composite materials are diced into a plurality of thermoelectric cells. The plurality of thermoelectric cells includes N-type cells and P-type cells.

The method may include forming a plurality of electrically conductive pads on a top substrate such that a majority of electrically conductive pads on the top substrate are paired through electrically conductive leads. The method may also include forming a plurality of electrically conductive pads on a bottom substrate such that a majority of electrically conductive pads on the bottom substrate are paired through electrically conductive leads.

Furthermore, the method may include bonding the cell substrate of each of the plurality of thermoelectric cells to the plurality of electrically conductive pads on the bottom substrate, and bonding a top layer of each of the plurality of thermoelectric cells to the plurality of electrically conductive pads on the top substrate. The top layer of a thermoelectric cell may be the layer of the thermoelectric cell which is furthest away from the cell substrate. The plurality of thermoelectric cells may include N-type cells and P-type cells. Also, the top substrate and the bottom substrate may be flexible. The thermoelectric cells may be connected to each other in series through the electrically conductive leads bridging pairs of electrically conductive pads, such that a first cell substrate is connected to a second cell substrate, and a first top layer is connected to a second top layer.

The top substrate and bottom substrate may be made of a metal-clad polyimide film and/or a metal-clad thermally conductive and dielectric plastic. The plurality of electrically conductive pads and electrically conductive leads may be formed by etching the metal-clad top and bottom substrates. The top substrate and bottom substrate may be laminated together after the plurality of thermoelectric cells have been connected to each other in series through the electrically conductive leads and the plurality of electrically conductive pads.

The method may include applying solder paste to each of the plurality of electrically conductive pads. The bonding of the cell substrate of each of the plurality of thermoelectric cells to the plurality of electrically conductive pads on the bottom substrate and the bonding of the top layer of each of the plurality of thermoelectric cells to the plurality of electrically conductive pads on the top substrate may be accomplished using solder reflow.

The method may further include depositing a barrier layer between at least one thin film thermoelectric layer and at least one thin film conduction layer. The barrier layer may be electrically conductive and may have a higher melting temperature than either of the at least one thin film thermoelectric layer and the at least one thin film conduction layer being separated by the barrier layer.

The method may also include depositing a seed layer between the cell substrate and one of the thin film thermoelectric layers. The seed layer may be electrically conductive, and may be an epoxy, a polymer film, a metallic compound applied as a thin film, and/or a material with a crystal structure which is intermediate to that of the cell substrate and the thin film thermoelectric layer.

Finally, the method may include depositing a conductive adhesive layer between one of the at least one thin film thermoelectric layer and one of the at least one thin film conduction layer. The conductive adhesive layer may be electrically conductive, and may be an epoxy, a polymer film, a metallic compound applied as a thin film, and/or a material with a crystal structure which is intermediate to that of the thin film conduction layer and the thin film thermoelectric layer.

In yet another aspect, a thin film thermoelectric device includes a plurality of thermoelectric cells. Each thermoelectric cell includes a cell substrate, at least one thin film thermoelectric layer above the cell substrate, and at least one thin film conduction layer above the at least one thin film thermoelectric layer.

Each of the thin film thermoelectric layers are separated by one of the at least one thin film conduction layers. The cell substrate is a metallic foil. The thin film thermoelectric device also includes a top substrate, a bottom substrate, and a plurality of electrically conductive pads disposed upon the top substrate and bottom substrate. The plurality of thermoelectric cells include N-type cells and P-type cells.

A top layer of a thermoelectric cell is the layer of the thermoelectric cell which is furthest away from the cell substrate. Also, the cell substrate and the top layer of each thermoelectric cell are connected to the plurality of electrically conductive pads. The thermoelectric cells are connected to each other in series through electrically conductive leads bridging pairs of electrically conductive pads, such that a first cell substrate is connected to a second cell substrate, and a first top layer is connected to a second top layer. Finally, the top substrate and the bottom substrate are flexible.

The methods and apparatus disclosed herein may be implemented in any means for achieving various aspects. Other features will be apparent from the accompanying drawings and from the detailed description that follows.

### BRIEF DESCRIPTION OF THE DRAWINGS

The embodiments of this invention are illustrated by way of example and not limitation in the Figures of the accompanying drawings, in which like references indicate similar elements and in which:

FIG. 1 shows a thin film thermoelectric device view of a thermoelectric cell 100 comprising at least one thin film thermoelectric layer and at least one thin film conduction layer placed in a temperature gradient, according to one embodiment.

FIG. 2 shows an exploded device view of a thin film thermoelectric device comprising N-type cells and P-type cells, and an exploded cell view of a thermoelectric cell, according to another embodiment.

FIG. 3 shows a device schematic view of a thin film thermoelectric device comprising N-type cells and P-type cells connected in series, according to one embodiment.

FIG. 4 shows an exploded layer view of a conductive adhesive layer between a thin film thermoelectric layer of FIG. 1 and a thin film conduction layer of FIG. 1, according to one embodiment.

FIG. 5 shows a device implementation view of the thin film thermoelectric device of FIGS. 1 and 2 placed in a temperature gradient, according to one embodiment.

FIG. 6 shows a mobile device view of the thin film thermoelectric device of FIGS. 1 and 2 used in conjunction with a mobile device battery, according to one embodiment.

FIG. 7 shows a solar application view of the thin film thermoelectric device of FIGS. 1 and 2 used in conjunction with a solar panel, according to one embodiment.

FIG. 8 shows a solar and thermoelectric device view of the thin film thermoelectric device of FIGS. 1 and 2 used in conjunction with a solar device, according to one embodiment.

FIG. 9 shows a process flow to produce thin film thermoelectric devices from layered composite materials, according to one embodiment.

Other features of the present embodiments will be apparent from the accompanying drawings and from the detailed description that follows.

### DETAILED DESCRIPTION

Example embodiments, as described below, may be used to provide a method and/or an apparatus of voltage generation across temperature differentials through a thin film thermoelectric device. Although the present embodiments have been described with reference to specific example embodiments, it will be evident that various modifications and changes may be made to these embodiments without departing from the broader spirit and scope of the various embodiments.

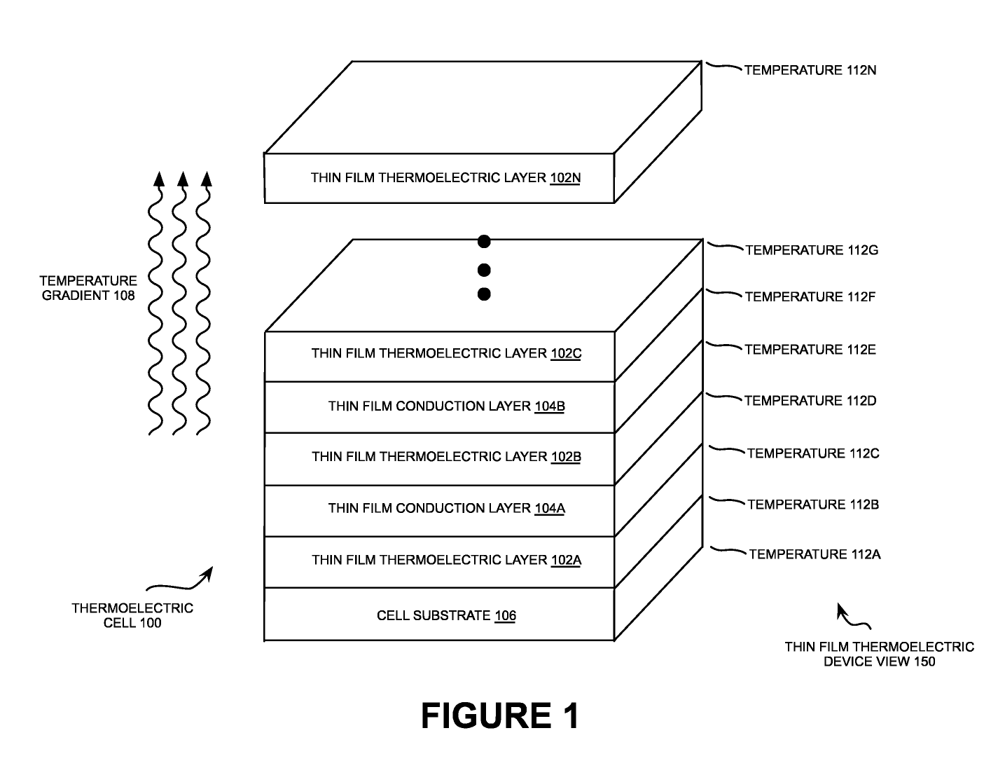

FIG. 1 shows a thin film thermoelectric device view 150 of a thermoelectric cell 100 comprising at least one thin film thermoelectric layer 102 and at least one thin film conduction layer 104 placed in a temperature gradient 108, according to one embodiment. Particularly, FIG. 1 shows a thermoelectric cell 100, the at least one thin film thermoelectric layer 102, the at least one thin film conduction layer 104, a cell substrate 106, the temperature gradient 108, and a plurality of temperatures 112A-N.

A thermoelectric cell 100 may be a device which converts heat (i.e. a temperature 112 differential) directly into electrical energy. A cell substrate 106 may be a substance or material which underlies the thermoelectric cell 100, and upon which various layers of material may be applied. A thin film thermoelectric layer 102 may be a layer of thermoelectric material which has been applied as a thin film, whose thickness may range from sub-nanometer to micrometers.

Example thermoelectric materials include, but are not limited to, Bi₂Te₃, ZnSb, PbTe, Zn₄Sb₃, AgPb₁₈SbTe₂₀ filled skutterudites, Bi₂Te₃/Sb₂Te₃ Superlattices, PbSeTe/PbTe quantum dots, Si₁₋ₓGeₓ, CsBi₄Te₆, AgPbₘSbTe₂₊ₘ, Yb_{0.19}Co₄Sb₁₂, and CeFe₄₋ₓCoₓSb₁₂. Thin films may be applied in a number of ways including, but not limited to, chemical deposition (e.g. plating, spin coating, the sol-gel method, chemical vapor deposition, etc.) and physical deposition (e.g. molecular beam epitaxy, sputtering, etc.).

A thin film conduction layer 104 may be a layer of conductive material which has been applied as a thin film. Example conductive materials include, but are not limited to, aluminum and nickel. A temperature 112 may be a comparative measurement of the heat present in an object, or part of an object. A temperature gradient 108 may be an increase or decrease in the temperature observed in passing from one point to another. A sputtering process may be a process in which atoms are ejected from a solid target material due to the bombardment of the target by energetic particles, such as electrons or highly charged ions.

In various embodiments, the conductive layer 104 may be aluminum foil. A temperature gradient 108 may be not parallel to the layers in the thermoelectric cell 100. A different temperature 112 may exist at each stratum of the thermoelectric cell 100. For example, temperature 112A may be 100 degrees, temperature 112B may be 101 degrees, and so forth with temperature 112N being n degrees, according to one embodiment. There may be a temperature differential between each stratum of the thermoelectric cell 100.

In one embodiment, a thin film thermoelectric device 200 includes at least one thermoelectric cell 100. Each thermoelectric cell 100 includes a cell substrate 106, at least one thin film thermoelectric layer 102 above the cell substrate 106, and at least one thin film conduction layer 104 above the at least one thin film thermoelectric layer 102. Each of the thin film thermoelectric layers 102 are separated by one of the at least one thin film conduction layers 104.

Furthermore, the at least one thin film thermoelectric layer 102 and the at least one thin film conduction layer 104 may be deposited using a sputtering process. Additionally, the at least one thin film thermoelectric layer 102 may be no thicker than 5 microns, and the at least one thin film conduction layer 104 may be between 1 microns and 15 microns.

A thermoelectric device, e.g. the thermoelectric cell 100, produces electrical power from heat flow across a temperature gradient 108, as shown in FIG. 1. As the heat flows from hot to cold, free charge carriers (electrons and/or holes) in the material are also driven to the cold end. The resulting voltage (V) is proportional to the temperature difference (ΔT) via the Seebeck coefficient, α, (V=αΔT). By connecting an electron-conducting (N-type) and hole-conducting (P-type) material in series, a net voltage may be produced that can be driven through a load. A good thermoelectric material has a Seebeck coefficient close to 100 μV/K; thus, in order to achieve a few volts at the load, many thermoelectric couples may need to be connected in series to make the thermoelectric device.

Thermoelectric power generation may be a means of generating power by converting thermal energy into electric energy. The efficiency (η) of converting thermal energy into electric energy of the thermoelectric conversion material depends on the ZT value (ZT) of the thermoelectric conversion material. The thermoelectric device may be a heat engine and hence limited by Carnot efficiency {ηc=(TH−TC)/TH}. The ZT value (ZT) is determined by the equation, ZT=(α²σT/K), according to the Seebeck coefficient α, also referred to as “thermoelectric coefficient”, electric conductivity (σ), thermal conductivity (K) of the thermoelectric material, and absolute temperature (T).

The thermoelectric cell 100 may reduce thermal conductivity and not impact electrical conductivity at much lower cost. A thin-film thermoelectric material (e.g. 10-micron Bismuth Telluride Bi2Te3) may be deposited on to a metal film, for example, aluminum foil, readily available at a super market. Once deposited, the film may be cut into a desired shape and size and stacked vertically on top of other film layers. There may be a spacer layer for electrical insulation between the alternate layers of thermoelectric material. The spacer may be removed so that the thermoelectric layers may be electrically connected in series with metal in between across a thermal gradient, across a temperature difference where the bottom of the device is hot and top is cold.

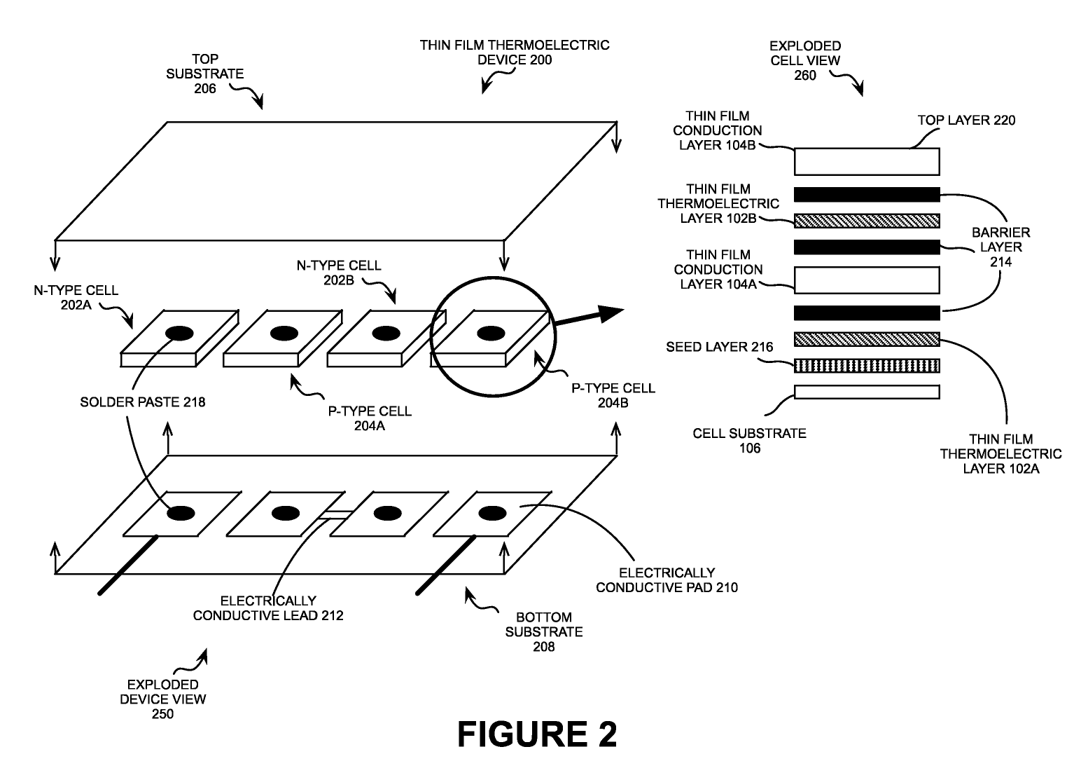

FIG. 2 shows an exploded device view 250 of a thin film thermoelectric device 200 comprising N-type cells 202 and P-type cells 204, and an exploded cell view 260 of a thermoelectric cell 100, according to another embodiment. Particularly, FIG. 2 shows the thin film thermoelectric device 200, the N-type cells 202, the P-type cells 204, a top substrate 206, a bottom substrate 208, an electrically conductive pad 210, an electrically conductive lead 212, a barrier layer 214, a seed layer 216, solder paste 218, and a top layer 220, in addition to the cell substrate 106, the thin film thermoelectric layer 102, and the thin film conduction layer 104 of FIG. 1.

A thin film thermoelectric device 200 may be a thermoelectric device employing materials which have been applied as thin films. It should be noted that one example of a thin film thermoelectric device 200 would be a single thermoelectric cell 100. Another example would be a plurality of thermoelectric cells 100 connected in series. In the context of the present description, a thin film thermoelectric device 200 may refer to a single thermoelectric cell 100, or a plurality of connected cells, or a plurality of connected cells packaged between two flexible substrates.

An N-type cell 202 may be a thermoelectric cell 100 in which the primary charge carrier is an electron. A P-type cell 204 may be a thermoelectric cell 100 in which the primary charge carrier is a positive hole. A top substrate 206 may be a substance or material which is placed above one or more thermoelectric cells 100, and which provides structure. A bottom substrate 208 may be a substance or material which is placed below one or more thermoelectric cells 100, and which provides structure.

An electrically conductive pad 210 may be a flat area on a substrate to which components (e.g. electrically conductive leads 212, thermoelectric cells 100, etc.) may be attached to make an electrical connection. A top layer 220 may be the layer of a thermoelectric cell 100 which is furthest away from the cell substrate 106.

An electrically conductive lead may be wire or other conducting material which connect two points of a circuit together. A solder paste 218 may be powdered metal solder suspended in a thick flux, used to connect surface mounted components electrically. In some embodiments, it may be applied using a screen-printing process. In other embodiments, it may be applied using a stencil.

A barrier layer 214 may be a layer of material which prevents the corruption (e.g. diffusion, sublimation, etc.) of one layer by another. It may also be known as a diffusion barrier. In many embodiments, a diffusion barrier may be a thin layer (e.g. micrometers thick) of metal sometimes placed between two other metals. It is done to act as a barrier to protect either one of the metals from corrupting the other. Example barrier layer 214 materials include, but are not limited to, cobalt, nickel, tungsten, ruthenium, tantalum, tantalum nitride, indium oxide, tungsten nitride, and titanium nitride.

A seed layer 216 may be a layer which assists in the bonding of a thermoelectric layer with the cell substrate 106. A seed layer 216 may be used as a thin film (e.g. sub-micron thick) to promote particular crystal growth and an adhesion to the substrate. Metallic elements have strong tendency to crystallize at low temperature, even on amorphous substrates such as glass or Kapton, thus a seed layer 216 containing metallic elements can have a preferred crystal orientation, which can serve to promote the formation of a thermoelectric layer with a desired crystalline structure. Example seed layer 216 materials include, but are not limited to, cobalt, nickel, tungsten, ruthenium, tantalum, tantalum nitride, indium oxide, tungsten nitride, and titanium nitride.

An epoxy may be a conductive adhesive based upon a metallic compound, such as silver. A polymer film may be a conductive film made up of an organic polymer, such as an intrinsically conducting polymer. A metallic compound may be a compound comprising one or more metals. A material with a crystal structure which is intermediate to that of the cell substrate 106 and the thin film thermoelectric layer 102 may be a conductive material whose structure is amenable to bonding between both materials. A layered composite material may be a material made up of multiple thin film layers applied to a substrate. The layered composite material may be produced on a large piece of cell substrate 106, and then later diced into multiple thermoelectric cells 100.

As shown, the N-type cells 202 and the P-type cells 204 are electrically connected to the electrically conductive pads 210, which are in turn connected through electrically conductive leads 212, resulting in the cells being connected to each other in series. In various embodiments, the top substrate 206 may be laminated to the bottom substrate 208, resulting in a flexible thermoelectric device.

The thin film thermoelectric device 200 may further include a plurality of thermoelectric cells 100, including N-type cells 202 and P-type cells 204. The thin film thermoelectric device 200 may also include a top substrate 206, a bottom substrate 208, and a plurality of electrically conductive pads 210 disposed upon the top substrate 206 and bottom substrate 208. The top layer 220 of a thermoelectric cell 100 may be the layer of the thermoelectric cell 100 which is furthest away from the cell substrate 106.

The cell substrate 106 and the top layer 220 of each thermoelectric cell 100 may be connected to the plurality of electrically conductive pads 210. The thermoelectric cells 100 may be connected to each other in series through electrically conductive leads 212 bridging pairs of electrically conductive pads 210, such that a first cell substrate 106 is connected to a second cell substrate 106, and a first top layer 220 is connected to a second top layer 220. Furthermore, the top substrate 206 and the bottom substrate 208 may be flexible.

The thermoelectric cell 100 may include a barrier layer 214 between a thin film thermoelectric layer 102 and a thin film conduction layer 104. The barrier layer 214 may be electrically conductive and may have a higher melting temperature 112 than either of the thin film thermoelectric layer 102 the thin film conduction layer 104 being separated by the barrier layer 214.

The thermoelectric cell 100 may further include a seed layer 216 between the cell substrate 106 and one of the at least one thin film thermoelectric layers 102. The seed layer 216 may be electrically conductive, and may be an epoxy, a polymer film, a metallic compound applied as a thin film, and/or a material with a crystal structure which is intermediate to that of the cell substrate 106 and the thin film thermoelectric layer 102.

In another embodiment, a method of producing a thin film thermoelectric device 200 includes producing at least two layered composite materials. The layered composite materials are produced by depositing at least one thin film thermoelectric layer 102 onto a cell substrate 106, and depositing at least one thin film conduction layer 104, such that each of the at least one thin film thermoelectric layer 102 are separated by one of the at least one thin film conduction layer 104. Next, the at least two layered composite materials are diced into a plurality of thermoelectric cells 100. The plurality of thermoelectric cells 100 includes N-type cells 202 and P-type cells 204.

The method may include forming a plurality of electrically conductive pads 210 on a top substrate 206 such that a majority of electrically conductive pads 210 on the top substrate 206 are paired through electrically conductive leads 212. The method may also include forming a plurality of electrically conductive pads 210 on a bottom substrate 208 such that a majority of electrically conductive pads 210 on the bottom substrate 208 are paired through electrically conductive leads 212.

Furthermore, the method may include bonding the cell substrate 106 of each of the plurality of thermoelectric cells 100 to the plurality of electrically conductive pads 210 on the bottom substrate 208, and bonding a top layer 220 of each of the plurality of thermoelectric cells 100 to the plurality of electrically conductive pads 210 on the top substrate 206. The top layer 220 of a thermoelectric cell 100 may be the layer of the thermoelectric cell 100 which is furthest away from the cell substrate 106.

The plurality of thermoelectric cells 100 may include N-type cells 202 and P-type cells 204. Also, the top substrate 206 and the bottom substrate 208 may be flexible. The thermoelectric cells 100 may be connected to each other in series through the electrically conductive leads 212 bridging pairs of electrically conductive pads 210, such that a first cell substrate 106 is connected to a second cell substrate 106, and a first top layer 220 is connected to a second top layer 220.

The method may include applying solder paste 218 to each of the plurality of electrically conductive pads 210. The bonding of the cell substrate 106 of each of the plurality of thermoelectric cells 100 to the plurality of electrically conductive pads 210 on the bottom substrate 208 and the bonding of the top layer 220 of each of the plurality of thermoelectric cells 100 to the plurality of electrically conductive pads 210 on the top substrate 206 may be accomplished using solder reflow.

The top substrate 206 and bottom substrate 208 may be made of a metal-clad polyimide film and/or a metal-clad thermally conductive and dielectric plastic. The plurality of electrically conductive pads 210 and electrically conductive leads 212 may be formed by etching the metal-clad top and bottom substrate 208s. The top substrate 206 and bottom substrate 208 may be laminated together after the plurality of thermoelectric cells 100 have been connected to each other in series through the electrically conductive leads 212 and the plurality of electrically conductive pads 210.

In yet another embodiment, a thin film thermoelectric device 200 includes a plurality of thermoelectric cells 100. Each thermoelectric cell 100 includes a cell substrate 106, at least one thin film thermoelectric layer 102 above the cell substrate 106, and at least one thin film conduction layer 104 above the at least one thin film thermoelectric layer 102. Each of the thin film thermoelectric layers 102 are separated by one of the at least one thin film conduction layers 104.

In one embodiment, the cell substrate 106 is a metallic foil. A metallic foil may be a metal compound which has been hammered or rolled into a thin, flexible sheet. The thin film thermoelectric device 200 also includes a top substrate 206, a bottom substrate 208, and a plurality of electrically conductive pads 210 disposed upon the top substrate 206 and bottom substrate 208. The plurality of thermoelectric cells 100 include N-type cells 202 and P-type cells 204.

A top layer 220 of a thermoelectric cell 100 is the layer of the thermoelectric cell 100 which is furthest away from the cell substrate 106. Also, the cell substrate 106 and the top layer 220 of each thermoelectric cell 100 are connected to the plurality of electrically conductive pads 210. The thermoelectric cells 100 are connected to each other in series through electrically conductive leads 212 bridging pairs of electrically conductive pads 210, such that a first cell substrate 106 is connected to a second cell substrate 106, and a first top layer 220 is connected to a second top layer 220. Finally, the top substrate 206 and the bottom substrate 208 are flexible.

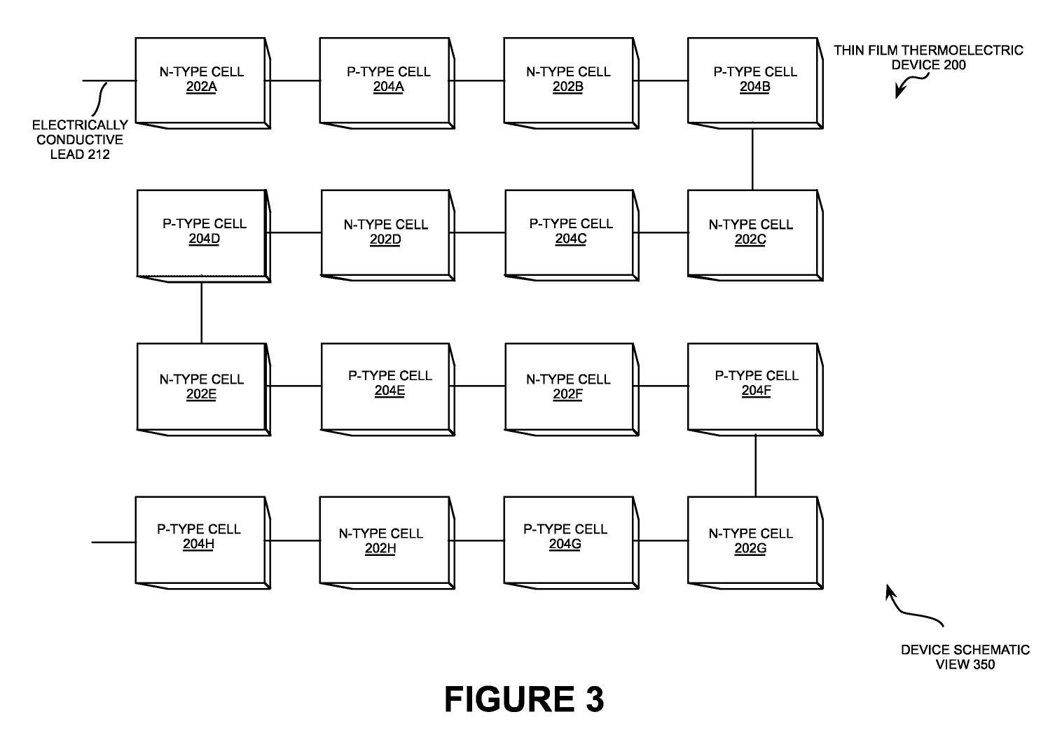

FIG. 3 shows a device schematic view 350 of a thin film thermoelectric device 200 comprising N-type cells 202 and P-type cells 204 connected in series, according to one embodiment. Particularly, FIG. 3 shows the thin film thermoelectric device 200, the N-type cells 202, the P-type cells 204, and the electrically conductive leads 212 of FIG. 2

The thin film thermoelectric device 200 may be in the form of an N-type cell 202202 and also in the form of a P-type cell 204, according to one embodiment. The thin film thermoelectric device 200 may also be in the form of a series of N-type and P-type cells. The thermoelectric cells 100 of each type of cell may be arranged in a series alternating between N-type cells 202 and P-type cells 204 in a grid formation. An electrically conductive lead 212 may connect each thermoelectric cell 100 in a series circuit, according to one embodiment. In various embodiments, though the cells are connected electrically in series, they may experience a temperature gradient 108 in parallel.

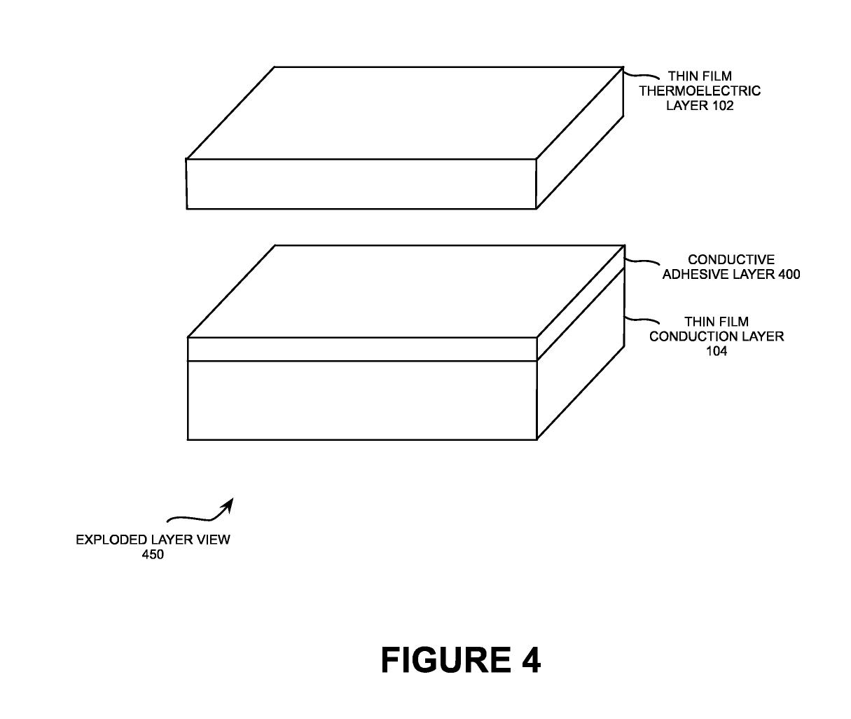

FIG. 4 shows an exploded layer view 450 of a conductive adhesive layer 400 between a thin film thermoelectric layer 102 of FIG. 1 and a thin film conduction layer 104 of FIG. 1, according to one embodiment. Particularly, FIG. 4 shows a conductive adhesive layer 400, the thin film thermoelectric layer 102 and thin film conduction layer 104 of FIG. 1.

A conductive adhesive layer 400 may be a layer of material which assists in the bonding of a thermoelectric or conduction layer with another layer. The thermoelectric cell 100 may further include a conductive adhesive layer 400 between at least one thin film thermoelectric layer 102 and at least one thin film conduction layer 104. The conductive adhesive layer 400 may be electrically conductive, and may be an epoxy, a polymer film, a metallic compound applied as a thin film, and/or a material with a crystal structure which is intermediate to that of the thin film conduction layer 104 and the thin film thermoelectric layer 102.

Where the thin film thermoelectric layer 102 and the thin film conduction layer 104 require adhesion, maybe because the materials of the thin film thermoelectric layer 102 and the thin film conduction layer 104 may not be amenable to adhesion through other methods, a conductive adhesive may be introduced to attach the layers, according to one embodiment. In another embodiment, the physical process of annealing may allow the thin film thermoelectric layer 102 and the thin film conduction layer 104 to adhere, where the materials of those layers may allow welding (metallurgical bonding not shown). In some embodiments, cold pressing and annealing may be employed to get the right properties for a higher ZT value of the device depending on the material system. For example, a composite device containing Bismuth Telluride may be annealed in vacuum or inert atmosphere around 300 degree Celsius.

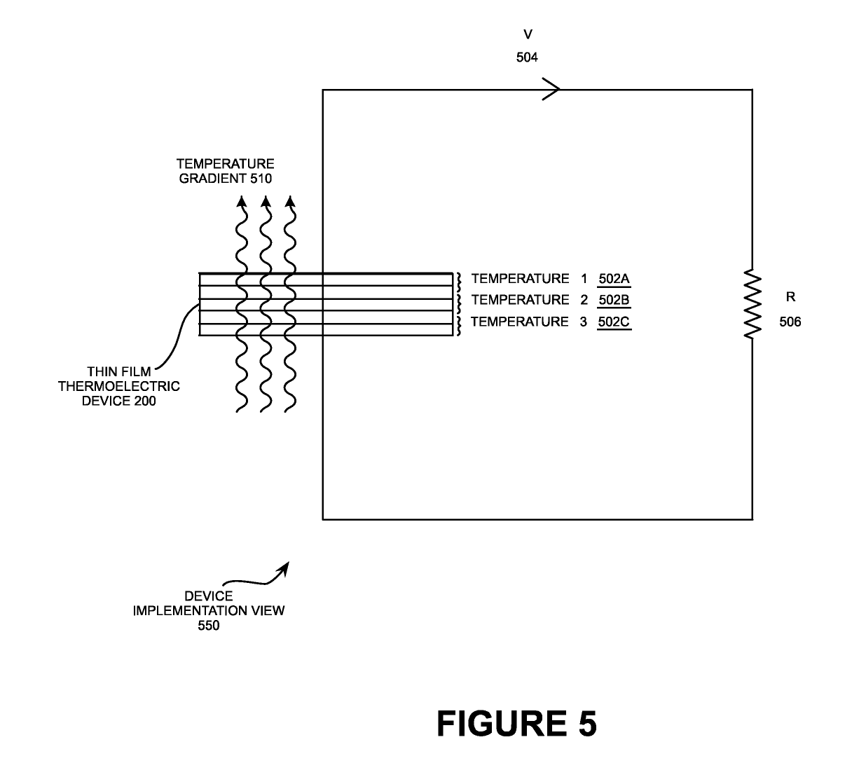

FIG. 5 shows a device implementation view 550 of the thin film thermoelectric device 200 of FIGS. 1 and 2 placed in a temperature gradient 108, according to one embodiment. Particularly, FIG. 5 shows a plurality of temperatures 502, a voltage 504, an internal resistance 506, and a temperature gradient 510, in addition to the thin film thermoelectric device 200 of FIG. 2. In some embodiments, the thin film thermoelectric device 200 may be a single thermoelectric cell 100, as shown.

A voltage 504 may be an electric energy charge difference of electric potential energy transported between two points. An internal resistance 506 may be the resistance which accounts for the voltage drop which occurs when a current is being driven by a power source. A wearable device may be any electronic device which is worn on one's person. Examples may include, but are not limited to, watches, jewelry, visors, goggles, earpieces, rings, and sensor bands (e.g. heart rate monitors worn on the chest or other body part, etc.).

A curved surface may be a surface which is bent, or having the form of a curve. Examples of curved surfaces upon which a flexible thin film thermoelectric device 200 may be employed include, but are not limited to, a pipe carrying hot liquids or materials, an exhaust pipe, and a water heater.

When there may be a temperature gradient 510 through the thin film thermoelectric device 200, with decreasing temperatures 502 at points along the depth of the device, the voltage 504 may be generated. An internal resistance 506 may be present in the electric circuit.

The thin film thermoelectric device 200 may be configured for use in a wide variety of applications, which may include a wearable device, a solar panel 702, a curved surface, a window, and/or a battery. Finally, the cell substrate 106 may be a metallic foil. The flexible nature of the thin film thermoelectric device 200 makes it well suited for applications where heat is being harvested from irregular, curved, or dynamic surfaces.

As a specific example, a device (e.g. health sensor, computing device, etc.) may be designed to be powered by a person's body heat. If the power source were to be rigid, the device may be uncomfortable to wear; furthermore, a rigid device may not be making contact with a person's body as efficiently as a device which is flexible, and can conform to the person's body.

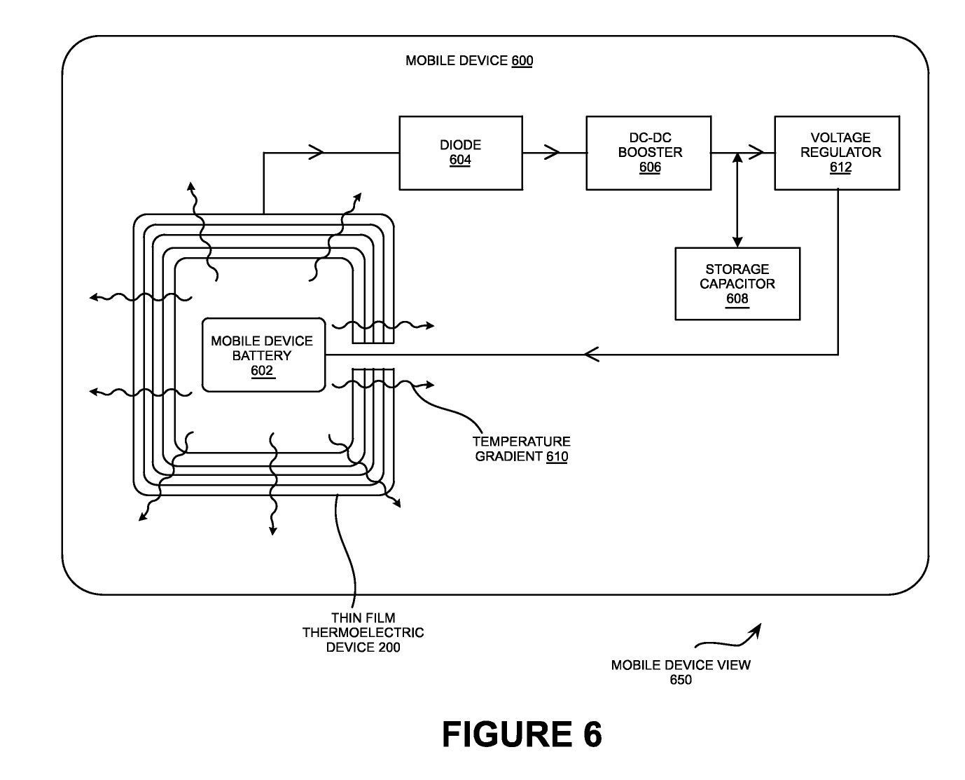

FIG. 6 shows a mobile device view 650 of the thin film thermoelectric device 200 of FIGS. 1 and 2 used in conjunction with a mobile device battery 602, according to one embodiment. Particularly, FIG. 6 shows a mobile device 600, a mobile device battery 602, a diode 604, a DC-DC booster 606, a storage capacitor 608, a temperature gradient 610, and a voltage regulator 612, in addition to the thin film thermoelectric device 200 of FIG. 2.

A mobile device 600 may be a portable electronic device, such as a mobile phone, a tablet, a laptop, and/or any other portable electronic device. A mobile device battery 602 may be a battery used in a mobile device 600, and which may generate a temperature gradient when in use. A diode 604 may be a semiconductor device which allows the flow of current in one direction only. A DC-DC booster 606 may be a device which takes one DC voltage and changes it into a larger DC voltage. A storage capacitor 608 may be a device used to store an electric charge, consisting of one or more pairs of conductors separated by an insulator. A voltage regulator 612 may be a device to automatically maintain a constant voltage level.

FIG. 6 illustrates a possible application of the thin film thermoelectric device 200. According to one embodiment, the thin film thermoelectric device 200 may be placed on and/or around a mobile device battery 602 and/or any heat-producing element of a device. The mobile device battery 602 may generate a temperature gradient 610 that passes through the thin film thermoelectric device 200 thereby generating voltage.

The thin film thermoelectric device 200 may be electrically coupled with a diode 604 to control the direction of flow of the current, which may be electrically coupled with a DC-DC booster 606 to enhance the voltage. The DC-DC booster 606 may be electrically coupled with a storage capacitor 608 to temporarily store the charge and with a voltage regulator 612 to regulate the output voltage. The storage capacitor 608 may be electrically coupled with the voltage regulator 612, according to one embodiment.

The thin film thermoelectric device 200 may be placed near a source of heat in the mobile device 600, e.g. the mobile device battery 602. The back of the mobile device 600 cover may be made out of metal that may act as a functional heat sink, according to one embodiment. Since the thin film thermoelectric device 200 has no thermal polarity, either inside the mobile device 600 or the outside atmosphere may act as heat sink or heat source depending on the temperature 112, according to one embodiment.

The thin film thermoelectric device 200 may produce continuously small power as the temperature fluctuates. The voltage produced by the thin film thermoelectric device 200 may be stored temporarily in a capacitor and trickle charge the mobile device battery 602 as needed. A software program may be written to control the output of the thin film thermoelectric device 200 and control and monitor other variables and attributes of the thin film thermoelectric device 200, according to one embodiment.

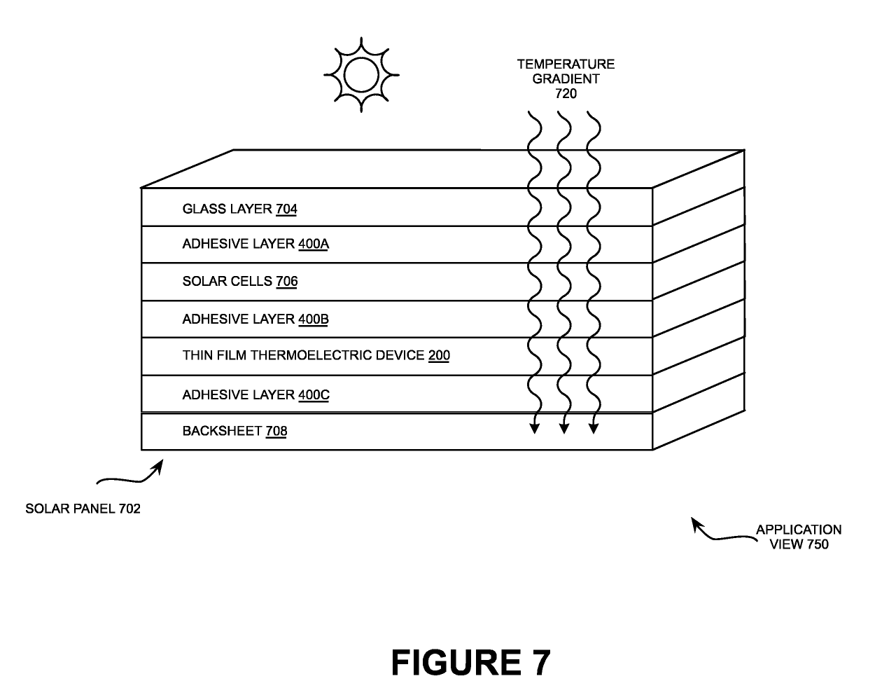

FIG. 7 shows a solar application view 750 of the thin film thermoelectric device 200 of FIGS. 1 and 2 used in conjunction with a solar panel 702, according to one embodiment. Particularly, FIG. 7 shows a solar panel 702, a glass layer 704, solar cells 706, a backsheet 708, and a temperature gradient 720, in addition to the conductive adhesive layer 400 of FIG. 4 and the thin film thermoelectric device 200 of FIG. 2.

A solar panel 702 may be a panel designed to absorb the sun's rays as a source of energy for generating electricity. A glass layer 704 may be a layer on the solar panel 702 made of glass or some other transparent materials. A solar cell 706 may be an electrical device which converts the energy of light directly into electricity by the photovoltaic effect. A backsheet 708 may be a backing used on a solar panel 702.

The thin film thermoelectric device 200 may be easily integrated into an existing solar panel 702 manufacturing process. Specifically, the thin film thermoelectric device 200 may be easily integrated into a panel assembly process with minimal changes to the existing assembly process. The voltage output of the thin film thermoelectric device 200 may be connected to the output of the solar panel 702 to boost the power output of the solar panel 702. The power output may be boosted orders of magnitude higher since the power density of the thin film thermoelectric device 200 may be 100× greater than the solar panel's power density.

The integration of the thin film thermoelectric device 200 into panel manufacturing may involve interconnecting thin film thermoelectric devices 200 placed below EVA (Ethylene Vinyl Acetate) and placed above another sheet of EVA below the thin film thermoelectric device 200, as shown in FIG. 7. The backsheet 708 may be replaced with higher thermal conductive layer, e.g. graphite, according to one embodiment. The whole stack may be laminated similar to the existing panel lamination process. Thermoelectric cells 100 may be connected using regular solder ribbon and paste similar to the current solar panel 702 manufacturing process, according to one embodiment.

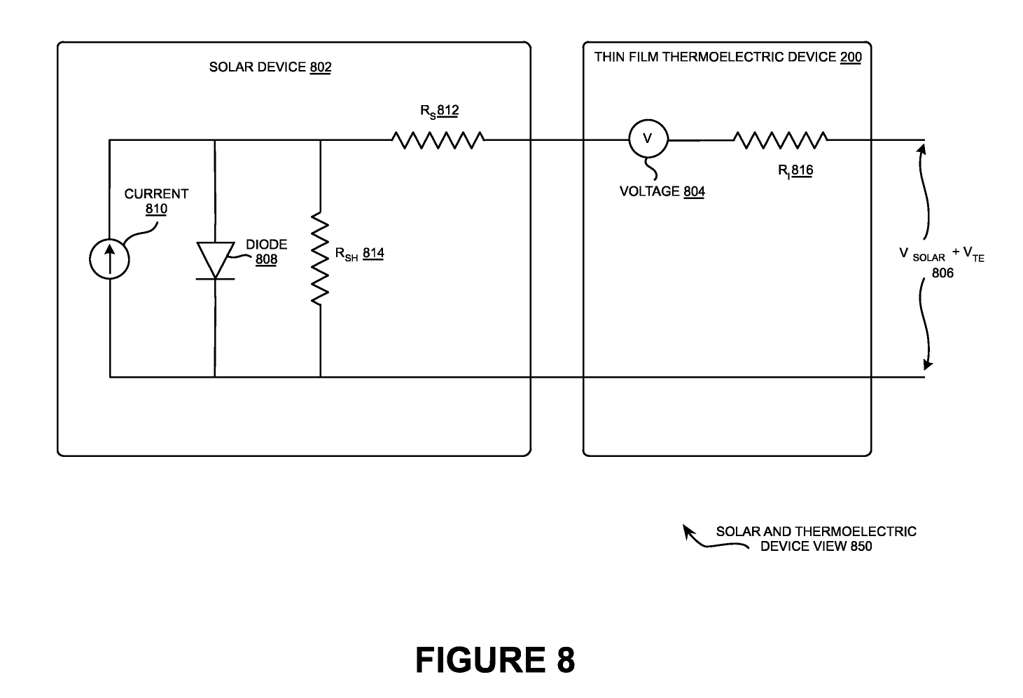

FIG. 8 shows a solar and thermoelectric device view 850 of the thin film thermoelectric device 200 of FIGS. 1 and 2 used in conjunction with a solar device 802, according to one embodiment. Particularly, FIG. 8 shows a solar device 802, a voltage, a total voltage 806, a diode 808, a current 810, a series resistance 812, shunt resistance 814, and an internal resistance, in addition to the thin film thermoelectric device 200 of FIG. 2.

A solar device 802 may be a device which generates power using solar energy. A total voltage 806 may be the sum of the voltage of the thin film thermoelectric device 200 and the voltage of the solar device 802. A current 810 may be a quantity representing the rate of flow of electric charge. A series resistance 812 may be a resistance present in a model of a solar cell 706 which accounts for the fact that the solar cell 706 is not ideal, and deviates from the model of a diode 808 in parallel with a current 810 source. A shunt resistance 814 may be a resistance present in a model of a solar cell 706 which accounts for the fact that the solar cell 706 is not ideal, and deviates from the model of a diode 808 in parallel with a current 810 source. Specifically, a shunt resistance 814 may account for the resistance in a short circuit within a solar cell 706.

Solar and thermoelectric device view 850 shows an equivalent circuit of connecting a solar device 802 and/or a cell output in electrical series with a thin film thermoelectric device 200. The thin film thermoelectric device 200 generates a voltage 804 and may have an internal resistance (R_{I} 816). The expected lossless output voltage will be the sum of the solar device 802 voltage and the thin film thermoelectric device 200 voltage (Vₛₒₗₐᵣ+V_{TE} 806). The thin film thermoelectric device 200 may need to have a low enough internal resistance (R_{I} 816) to convey a photo-generated current 810 without sacrificing the photovoltaic fill factor. Concomitantly, a large number of p-n cells may be preferred to drive a high Seebeck voltage in the thin film thermoelectric device 200. The solar device 802 may have a series resistance 812 (R_{S} 812) and a shunt resistance 814 (R_{SH} 814). The solar device 802 may include a diode 808.

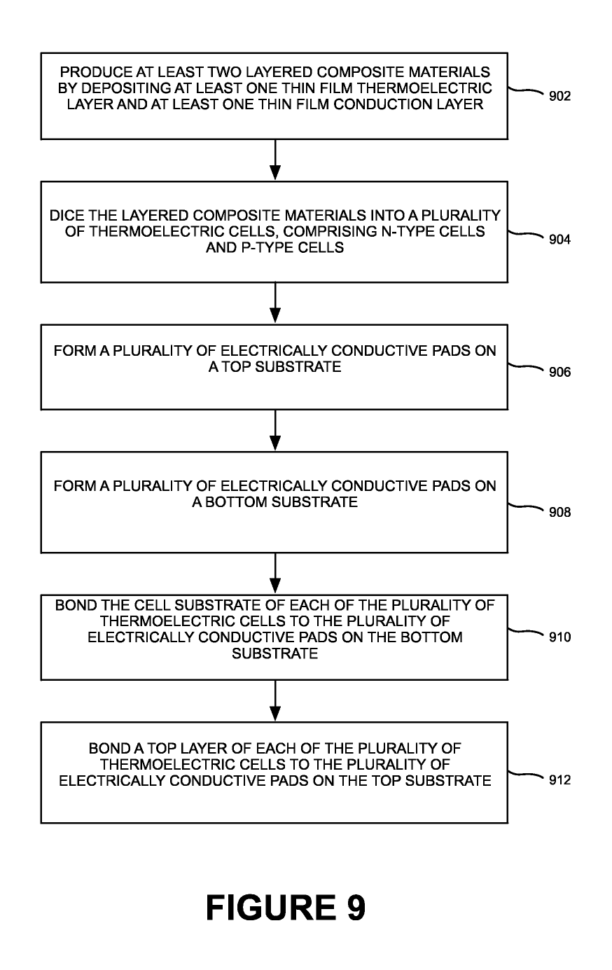

FIG. 9 shows a process flow to produce thin film thermoelectric devices 200 from layered composite materials, according to one embodiment. In operation 902, at least two layered composite materials may be produced by depositing at least one thin film thermoelectric layer 102 and at least one thin film conduction layer 104. In operation 904, the layered composite materials may be diced into a plurality of thermoelectric cells 100, comprising N-type cells 202 and P-type cells 204.

In operation 906, a plurality of electrically conductive pads 210 may be formed on a top substrate 206. In operation 908, a plurality of electrically conductive pads 210 may be formed on a bottom substrate 208. In operation 910, the cell substrate 106 of each of the plurality of thermoelectric cells 100 may be bonded to the plurality of electrically conductive pads 210 on the bottom substrate 208. In operation 912, a top layer 220 of each of the plurality of thermoelectric cells 100 may be bonded to the plurality of electrically conductive pads 210 on the top substrate 206.

Low efficiency, high operating temperature combined with higher cost forbid current thermoelectric devices for wider market adoption. Low efficiency may relegate thermoelectric devices to a few applications where their simplicity and ruggedness may outweigh the inefficiency, such as sensors and waste-heat-energy converters. The potential for thermoelectric devices, however, may be much greater. If their efficiency may be increased and reduce the operational temperatures near room temperature (300K), thermoelectric devices may begin to supplant mechanical compressor refrigeration systems, gasoline generators, geothermal power production, and more. Thermoelectric devices may play a significant role in the energy production, home heating/cooling and general energy management of the future.

Low thermal conductivity with higher electrical conductivity is needed for higher ZT. Unfortunately there are no single materials that possess simultaneously higher electrical conductivity and lower thermal conductivity. Most of the recent efforts in research community thus have been reducing thermal conductivity by phonon blocking and/or phonon scattering and/or reducing phonon free mean path.

Thermoelectric devices may be made out of bulk material in the form of ingots and/or pellets. The ingot may be formed from liquid melt and/or from the powder metallurgy route. Each pellet may be attached on a substrate and form a module.

Recent advancements may be made using a thin-film process that allows forming micro bumps using common semiconductor equipment. This allows thousands of micro bumps to form a thermoelectric device to produce meaningful voltage and power output.

Metal particles may be incorporated in a thermoelectric material to form a composite structure. Nanophase metal particles in a polymer matrix may be utilized to form a composite thermoelectric device. Ceramic nanoparticles may be introduced as phonon scattering centers in a thermoelectric device to improve the figure of merit (ZT), which may occur with nano-carbon material units in a thermoelectric matrix.

Quantum super lattice structures may be limited to expensive composite thermoelectric materials and methods and thus limiting the wide spread use of such devices in common market place. Thermoelectric components may be placed in series, but the thermal conductivity may be diminished because the interconnections between the semiconductors may create thermal shorting.

There may be no material that possesses High Electrical Conductivity and Low Thermal Conductivity simultaneously. Another limitation in current art is each material may behave differently at different temperatures 112. A thermoelectric cell approach with a flexible substrate may permit stacking. Stacking allows combining different materials with different properties, and may be with or without a spacer. Thermoelectric elements may be connected electrically in series, but thermally in parallel across a temperature gradient. Stacking may allow manufacturers to control electrical conductivity and thermal conductivity independently, and may be able to stack different materials. In one embodiment, the stacked layer may be a single N-type or P-type stack. Additionally, there may be a super lattice for each layer.

A thermoelectric device (e.g., the thermoelectric cell 100, the thin film thermoelectric device 200, etc.) may be based on a multilayer structure having alternate layers of metal and thermoelectric material, according to one embodiment. Thermoelectric material may be deposited via sputtering and/or a similar thin-film deposition technique onto a conducting substrate like aluminum and/or any other metal film. In one embodiment, sputtered thermoelectric material onto aluminum foil may be cut and/or diced into a square and/or rectangular piece and/or stacked on top of other layers to result in a higher figure of merit (ZT).

In another embodiment, different thermoelectric materials sputtered onto different metal films may be stacked on top of each other to obtain lower thermal conductivity and higher electrical conductivity resulting in a higher figure of merit. A thermoelectric device with a high figure of merit may be achieved by arranging alternate layers of different metal/material combination in a variety of configurations, according to one embodiment.

A refrigerating effect may be obtained in the thermoelectric cell 100 by passing current along a circuit containing dissimilar materials, according to one embodiment. Heat may be absorbed at one junction of the two materials and heat may be released at the other junction, according to one embodiment.

The transfer of heat may be caused by the change in electron energy levels when electrons access the conduction band as defined by quantum physics. The conduction band varies with each material, which means that conducting electrons in some materials may be at a higher energy level than in other materials. When electrons pass down a circuit of dissimilar materials, the electrons alternately extract energy and/or release energy with each change in the conduction band.

The desired refrigerating effect may occur when electrons move to a higher energy level upon change of material. A reverse effect may also occur when electricity is generated from a circuit of dissimilar materials that may be exposed to a temperature differential. This is the physical principle that forms the basis of the thermocouple and is known as the Seebeck effect. The Peltier and Seebeck effects are complementary manifestations of the same physical phenomenon.

There are other applications for the thin film thermoelectric device 200. Voltage generation from temperature differentials in a wide array of situations in different fields offer the potential for application of the thin film thermoelectric device 200. The thin film thermoelectric device 200 may be used in medical applications, e.g. cochlear hearing replacements and devices, nerve stimulation implants; consumer applications, e.g. watches, self-powered toys and novelties; military applications, e.g. wireless personal area networks, ammunition safety sensors, space programs, building environmental control and security.

The thin film thermoelectric device 200 may be integrated to power industrial and/or commercial devices, e.g. wireless sensor networks, automobile tire pressure monitors, wireless HVAC sensors, wireless lighting an energy controls, wireless industrial process control sensors, and oil and gas well head sensors. The thin film thermoelectric device 200 may provide ecological and/or energy applications, e.g. secondary power generation/recovery, electric generation grid device monitor sensors, and environmental condition sensors.

In the field of building automation, the thin film thermoelectric device 200 may have practical applications in security, HVAC, automatic meter reading, lighting control, and access control. In the area of personal health care, the layer composite may have applications in patient monitoring and fitness monitoring. The thin film thermoelectric device 200 may have industrial control applications, e.g. asset management process control and environmental energy management.

Consumer electronics applications may include televisions, VCRs, DVD/CD remotes and/or players, mobile phones, tablets, laptops, household appliances, computer mice, keyboards, joysticks, and/or personal computers and computing peripherals. Residential/light commercial control applications of the layer composite may include security, HVAC, lighting control, access control, and/or lawn & garden irrigation systems.

By not relying on traditional semiconductor-manufacturing techniques, the thin film thermoelectric device 200 may allow the electrical path generated through the thin film thermoelectric device 200 to be in parallel with the thermal gradient, according to one embodiment. Instead of running perpendicular to the heat gradient under semiconductor-manufacturing techniques, the electrical path in the thin film thermoelectric device 200 may run parallel to the heat gradient because of the layering structure of the thermoelectric cells 100.

In one embodiment, while thermally conductive, the thin film thermoelectric device 200 may effectively maintain the temperature differential between opposite ends of the thin film thermoelectric device 200. Thereby, the thin film thermoelectric device 200 may create temperature differentials that may be persistent and thus may optimize the voltage generation from a temperature gradient.

The resistance to heat transfer attributable to the thin film thermoelectric device 200 perpetuates the overall temperature differential and thus may effectively sustain the temperature gradient across each stratum of the thermoelectric cells 100 and accordingly the thin film thermoelectric device 200 as a whole. Because of this resistance to heat transfer, the thin film thermoelectric device 200 may serve as a more efficient means of voltage generation since the temperature differentials at each layer of the thermoelectric cells 100 may not require additional heat sinks and/or energy-intensive cooling techniques that may be employed to maintain the temperature differential.

While serving as a thermoelectric device, the material composition of the thermoelectric cell 100 may be altered and adjusted according to the specific needs of each application. The thin film thermoelectric device 200 is material independent. If the application of the thin film thermoelectric device 200 requires a specific temperature range, e.g. environments with temperatures higher than 800 degrees K, then a particular material may be employed in the thermoelectric cell 100. For example, Bismuth Telluride may be appropriate in one temperature range, while Silicon Germanium may be more suitable in another temperature.

The thermoelectric cell 100 may include whatever material is most appropriate and best suited to the conditions of the application. Temperature may be one variable. Other factors may be electrical conductivity, malleability, texture, etc. Because the thin film thermoelectric device 200 is material independent, the material best suited for the relevant application may be chosen, thus optimizing the voltage generation and other properties for each application.

Additionally, because the thin film thermoelectric device 200 is material independent and because of the effectiveness of the thin film thermoelectric device 200 in maintaining a temperature gradient 108 across its strata, multiple types of materials may be employed in composing the thermoelectric cell 100. For example, the thermoelectric cell 100 may contain Cu2Te, Bi2Te3, and/or Sb2Te3, all in one cell.

Because the thermoelectric cell 100 may maintain a temperature differential effectively, materials impractical at one temperature may still be used in the thermoelectric cell 100 at a different layer with a different temperature where the material may be practical. For example, if the hot surface of the thin film thermoelectric device 200 precludes use of one material because it may melt and/or not be as thermally or electrically conductive at that temperature, that material may still be utilized at the cooler end of the thin film thermoelectric device 200 because the thin film thermoelectric device 200 maintains the temperature differential and the material may be used toward the cool surface of the thin film thermoelectric device 200. Thus, the thin film thermoelectric devices 200 characteristic of sustaining the temperature gradient may permit the combination of different materials and thereby optimize the inherent properties of component materials.

The thermoelectric cell 100 may also be produced without resorting to semiconductor processes. According to one embodiment, the thermoelectric cell 100 is produced by physically and/or mechanically depositing each layer and/or sol-gel and/or via sputtering and/or evoparation and/or any other thin-film deposition techniques. The thermoelectric cell 100 manufacture process may be relatively inexpensive and may involve less material cost. In one embodiment, the physical process of annealing may serve to bond the layers of the layer composite.

The production of the thermoelectric cell 100 by these means may optimize crystallinity in the physical structure of the thermoelectric cell 100, control grain growth, and maintain structural control. The thermoelectric cell 100 may be manufactured with these variables in mind and the production of the thermoelectric cell 100 may allow the manufacturer to control for these variables according the optimal parameters.

Additionally, according to one embodiment, the thin film thermoelectric device 200 has no size restrictions and thus lends itself to scaling. The thin film thermoelectric device 200 may be sized according to the application. For example, the layered composite material may be diced into smaller tile sections for use in a mobile device application, or alternatively, the layered composite material may be cut into relatively larger rectangular or square tiles for appropriate use in a solar panel 702, as shown in FIG. 7.

The thermoelectric cell 100 may have a stratum-like structure, according to one embodiment. Because the thermoelectric cell 100 inhibits the flow of heat across the layers, there may be a relatively smaller temperature differential per each layer. However, because the thermoelectric cell 100 may comprise as many layers as a manufacturer and/or consumer desire, according to one embodiment, the temperature differentials across each layer may sum up to a larger overall temperature differential across the entire cell.

The thermoelectric cell 100 as a thermoelectric device may harvest energy from waste heat at lower costs with a higher ZT value, higher efficiency, lower manufacturing costs, and may be easily integrated into existing manufacturing process systems for applications. The thin film thermoelectric device 200, because of its flexibility, may be used in other wearable electronics to utilize body heat.

A number of embodiments have been described. Nevertheless, it will be understood that various modifications may be made without departing from the spirit and scope of the claimed invention. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims. Furthermore, the specification and/or drawings may be regarded in an illustrative rather than a restrictive sense.

What is claimed is:

1. A thin film thermoelectric device, comprising:
at least one thermoelectric cell, each thermoelectric cell comprising:
a cell substrate;
at least one thin film thermoelectric layer above the cell substrate; and
at least one thin film conduction layer above the at least one thin film thermoelectric layer,
wherein each of the at least one thin film thermoelectric layer are separated by one of the at least one thin film conduction layer.

2. The thin film thermoelectric device of claim 1, further comprising:
a plurality of thermoelectric cells, comprising N-type cells and P-type cells;
a top substrate;
a bottom substrate; and
a plurality of electrically conductive pads disposed upon the top substrate and bottom substrate,
wherein a top layer of a thermoelectric cell is the layer of the thermoelectric cell which is furthest away from the cell substrate,
wherein the cell substrate and the top layer of each thermoelectric cell are connected to the plurality of electrically conductive pads,
wherein the thermoelectric cells are connected to each other in series through electrically conductive leads bridging pairs of electrically conductive pads, such that a first cell substrate is connected to a second cell substrate, and a first top layer is connected to a second top layer, and
wherein the top substrate and the bottom substrate are flexible.

3. The thin film thermoelectric device of claim 1, wherein the at least one thermoelectric cell further comprises:
a barrier layer between at least one thin film thermoelectric layer and at least one thin film conduction layer,
wherein the barrier layer is electrically conductive and has a higher melting temperature than either of the at least one thin film thermoelectric layer and the at least one thin film conduction layer being separated by the barrier layer.

4. The thin film thermoelectric device of claim 1, wherein the at least one thermoelectric cell further comprises:
a seed layer between the cell substrate and one of the at least one thin film thermoelectric layers,
wherein the seed layer is electrically conductive, and is at least one of an epoxy, a polymer film, a metallic compound applied as a thin film, and a material with a crystal structure which is intermediate to that of the cell substrate and the thin film thermoelectric layer.

5. The thin film thermoelectric device of claim 1, wherein the at least one thermoelectric cell further comprises:
a conductive adhesive layer between at least one thin film thermoelectric layer and at least one thin film conduction layer,
wherein the conductive adhesive layer is electrically conductive, and is at least one of an epoxy, a polymer film, a metallic compound applied as a thin film, and a material with a crystal structure which is intermediate to that of the thin film conduction layer and the thin film thermoelectric layer.

6. The thin film thermoelectric device of claim 1, wherein at least one of the at least one thin film thermoelectric layer and the at least one thin film conduction layer is deposited using a sputtering process.

7. The thin film thermoelectric device of claim 1, wherein the at least one thin film thermoelectric layer is no thicker than 5 microns, and the at least one thin film conduction layer is between 1 microns and 15 microns.

8. The thin film thermoelectric device of claim 1, wherein the thin film thermoelectric device is configured for use in at least one of a wearable device, a solar panel, a curved surface, and a battery.

9. The thin film thermoelectric device of claim 1, wherein the cell substrate is a metallic foil.

10. A method of producing a thin film thermoelectric device comprising:
producing at least two layered composite materials by:
depositing at least one thin film thermoelectric layer onto a cell substrate; and
depositing at least one thin film conduction layer, such that each of the at least one thin film thermoelectric layer are separated by one of the at least one thin film conduction layer,
dicing the at least two layered composite materials into a plurality of thermoelectric cells,
wherein the plurality of thermoelectric cells comprises N-type cells and P-type cells.

11. The method of claim 10, further comprising:
forming a plurality of electrically conductive pads on a top substrate such that a majority of electrically conductive pads on the top substrate are paired through electrically conductive leads;
forming a plurality of electrically conductive pads on a bottom substrate such that a majority of electrically conductive pads on the bottom substrate are paired through electrically conductive leads;
bonding the cell substrate of each of the plurality of thermoelectric cells to the plurality of electrically conductive pads on the bottom substrate; and
bonding a top layer of each of the plurality of thermoelectric cells to the plurality of electrically conductive pads on the top substrate,
wherein the top layer of a thermoelectric cell is the layer of the thermoelectric cell which is furthest away from the cell substrate,
wherein the plurality of thermoelectric cells comprise N-type cells and P-type cells,
wherein the top substrate and the bottom substrate are flexible, and
wherein the thermoelectric cells are connected to each other in series through the electrically conductive leads bridging pairs of electrically conductive pads, such that a first cell substrate is connected to a second cell substrate, and a first top layer is connected to a second top layer.

12. The method of claim 11, wherein:
the top substrate and bottom substrate are made of at least one of a metal-clad polyimide film and a metal-clad thermally conductive and dielectric plastic
the plurality of electrically conductive pads and electrically conductive leads are formed by etching the metal-clad top and bottom substrates, and
the top substrate and bottom substrate are laminated together after the plurality of thermoelectric cells have been connected to each other in series through the electrically conductive leads and the plurality of electrically conductive pads.

13. The method of claim 11, further comprising:
applying solder paste to each of the plurality of electrically conductive pads,
wherein the bonding of the cell substrate of each of the plurality of thermoelectric cells to the plurality of electrically conductive pads on the bottom substrate and the bonding of the top layer of each of the plurality of thermoelectric cells to the plurality of electrically conductive pads on the top substrate is accomplished using solder reflow.

14. The method of claim 10, further comprising:
depositing a barrier layer between at least one thin film thermoelectric layer and at least one thin film conduction layer,
wherein the barrier layer is electrically conductive and has a higher melting temperature than either of the at least one thin film thermoelectric layer and the at least one thin film conduction layer being separated by the barrier layer.

15. The method of claim 10, further comprising:
depositing a seed layer between the cell substrate and one of the at least one thin film thermoelectric layers,
wherein the seed layer is electrically conductive, and is at least one of an epoxy, a polymer film, a metallic compound applied as a thin film, and a material with a crystal structure which is intermediate to that of the cell substrate and the thin film thermoelectric layer.

16. The method of claim 10, further comprising:
depositing a conductive adhesive layer between one of the at least one thin film thermoelectric layer and one of the at least one thin film conduction layer,
wherein the conductive adhesive layer is electrically conductive, and is at least one of an epoxy, a polymer film, a metallic compound applied as a thin film, and a material with a crystal structure which is intermediate to that of the thin film conduction layer and the thin film thermoelectric layer.

17. The method of claim 10, wherein at least one of the at least one thin film thermoelectric layer and the at least one thin film conduction layer is deposited using a sputtering process.

18. The method of claim 10, wherein the at least one thin film thermoelectric layer is no thicker than 5 microns, and the at least one thin film conduction layer is between 1 microns and 15 microns.

19. The method of claim 11, wherein the thin film thermoelectric device is configured for use in at least one of a wearable device, a solar panel, a curved surface, and a battery.

20. A thin film thermoelectric device, comprising:
a plurality of thermoelectric cells, each thermoelectric cell comprising:
a cell substrate;
at least one thin film thermoelectric layer above the cell substrate;
at least one thin film conduction layer above the at least one thin film thermoelectric layer,
wherein each of the at least one thin film thermoelectric layer are separated by one of the at least one thin film conduction layer, and
wherein the cell substrate is a metallic foil;
a top substrate;
a bottom substrate; and
a plurality of electrically conductive pads disposed upon the top substrate and bottom substrate,
wherein the plurality of thermoelectric cells comprises N-type cells and P-type cells,
wherein a top layer of a thermoelectric cell is the layer of the thermoelectric cell which is furthest away from the cell substrate,
wherein the cell substrate and the top layer of each thermoelectric cell are connected to the plurality of electrically conductive pads,
wherein the thermoelectric cells are connected to each other in series through electrically conductive leads bridging pairs of electrically conductive pads, such that a first cell substrate is connected to a second cell substrate, and a first top layer is connected to a second top layer, and
wherein the top substrate and the bottom substrate are flexible.
